(19) United States
(12) Patent Application Publication
(10) Pub. No.: US 2011/0001469 A1
(43) Pub. Date: Jan. 6, 2011

(54) Unbiased non-polarized direct current voltage divider float circuit

(76) Inventor: JOSEPH PAUL RAU, Canyon Lake, CA (US)

Correspondence Address: JOSEPH RAU, 30345 Spray Drive, Canyon Lake, CA, 92587, US

(21) Appl. No.: 12/829,221

(22) Filed: Jul. 1, 2010

Related U.S. Application Data
(60) Provisional application No. 61/222,393, filed on Jul. 1, 2009.

(51) Int. Cl. G01R 1/06

(52) U.S. Cl. 324/149

(57) ABSTRACT

A non-polarized and high impedance voltage divider/float circuit may be used as a diagnostic instrument. The circuit may permit a non-polarized DC connection and permit greater voltage spans when illuminating polarity indicating devices. The diagnostic instrument of the present invention may be non-biased (that is, it may be hooked up to the power supply in either direction), may allow testing systems of various voltages and may be capable of seeing signals of opposite polarities simultaneously.

### CROSS REFERENCE TO RELATED APPLICATIONS

The present application claims the benefit of U.S. Provisional patent application No. 61/222,393, filed Jul. 1, 2009, which is herein incorporated by reference.

### BACKGROUND OF THE INVENTION

The present invention relates to electrical diagnostic instruments and, more particularly, to a non-biased diagnostic instrument for direct current (DC) electrical systems that may be used on systems of varied voltages.

Dual-lead volt-ohm-amp testers may be used to detect current in an electric system, but may require switching the two leads to detect opposite polarities. Conventional testers may not readily see signals of opposite polarities at the same time. Furthermore, conventional probes may be limited to testing systems of one particular voltage. Different probes may be needed to test systems with different voltages.

As can be seen, there is a need for a non-biased diagnostic instrument that may work with various system voltages and may detect opposite polarity signals simultaneously.

### SUMMARY OF THE INVENTION

In one aspect of the present invention, a diagnostic instrument comprises first and second leads adapted to connect to a direct current power source; first ends of first and second resistors in series in the first and second leads, respectively; second ends of first and second resistors joined together and connected to a first lead of a detector; and a probe attached to a second lead of the detector.

In another aspect of the present invention, a diagnostic instrument comprises a direct current power source; first and second leads connected to the power source; first ends of first and second resistors in series in the first and second leads, respectively; second ends of first and second resistors joined together and connected to a first lead of a light emitting diode (LED); and a probe attached, via a third resistor, to a second lead of the LED.

These and other features, aspects and advantages of the present invention will become better understood with reference to the following drawings, description and claims.

### BRIEF DESCRIPTION OF THE DRAWINGS

FIG. 1 is a schematic drawing of a diagnostic instrument circuit according to an embodiment of the present invention;

FIG. 2 is a flow chart describing the use of the diagnostic instrument circuit of FIG. 1; and

FIG. 3 is a schematic drawing of a diagnostic instrument circuit according to an alternate embodiment of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Various inventive features are described below that can each be used independently of one another or in combination with other features.

Broadly, an embodiment of the present invention provides a non-polarized and high impedance voltage divider/float circuit that may be used as a diagnostic instrument. The present invention may permit a non-polarized DC connection and permit greater voltage spans when illuminating polarity indicating devices. The diagnostic instrument of the present invention may be non-biased (that is, it may be hooked up to the power supply in either direction), may allow testing systems of various voltages and may be capable of seeing signals of opposite polarities simultaneously. The diagnostic instrument of the present invention may permit electrical troubleshooting through cause and effect polarities. The diagnostic instrument of the present invention may be non-biased and non-polarized, thereby creating a ground effect to allow both sides of the power source open to be readable accurately without switches. The non-polarized (ground) effect allows dual signals to be readable accurately from either polarity simultaneously (in an analog sense). In other words, the instrument does not switch digitally, thus allowing true sources to be readable without outside switching occurrences.

Referring to FIG. 1, a diagnostic instrument 10 may include a DC power source 12. The power source 12 may be a power supply, a battery or the like. In one embodiment of the present invention, the power source 12 may be a 6 volt DC battery. Lead wires 20, 22 from the power source 12 may go to inline resistors R1, R2 connected in series, allowing a non-polarized, high impedance, wide voltage range source connection. The two series-joined resistors may create a non-polarized, high impedance, wide voltage range voltage divider/float circuit. The series-joined resistors may connect to a single conductor 14 which may connect to one end of a detector, such as an illuminating LED 16 or center point meter. The other end of the LED 16 or center point meter may connect through a resistor R3 to a probe 18.

The lead wires 20 may include two insulated clips (not shown) on one end thereof to connect to the power supply 12. The LED 16 may be a tri-LED that may, for example, light a red light when the probe 18 detects a signal having a first polarity (such as a positive DC signal) and light a green light when the probe 18 detects a signal having a second, opposite polarity (such as a negative DC signal).

In one embodiment of the present invention, the resistors R1, R2 may have the same value and may be from about 500 ohm to about 1 meg (1×10⁶) ohm. When the power supply 12 is a 6V battery, the resistors R1, R2 may be 1,000 ohm resistors. Such a configuration may permit the probe 18 to detect voltages ranging from about 3 to about 90V. Unlike conventional detectors, that may be used for a single system, the diagnostic instrument 10 of the present invention may be a single device that may be used on a wide range of devices, such as 5V integrated circuits, 12V automobiles, 48V golf carts, and the like. The resistors R1, R2 may be changed to permit testing higher voltage circuits. For example, by using larger resistances, the diagnostic instrument 10 may be used to detect voltages up to, for example 500V.

In one embodiment of the present invention, the resistor R3 may be from about 5 to about 20 ohm, typically about 10 ohm. This resistor may help protect the circuit.

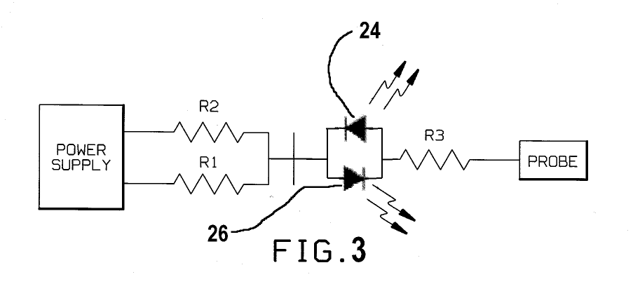

Referring to FIG. 3, the tri-LED 16 may be replaced with two separate LEDs 24, 26. These LEDs may be connected anode-to-cathode and cathode-to-anode, thereby permitting one LED to light when the probe detects one polarity and the other LED to light when the probe detects an opposite polarity.

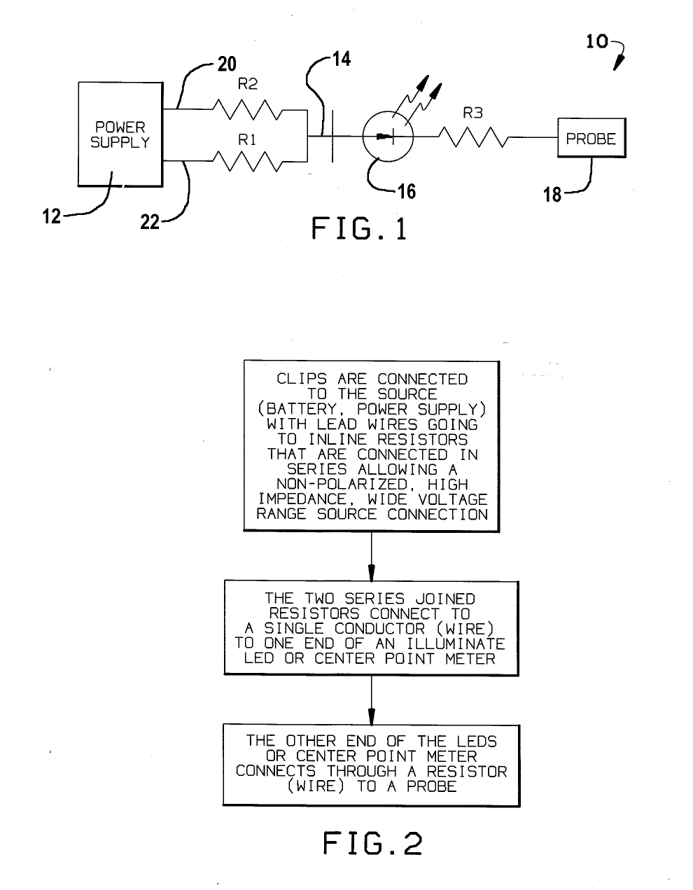

Referring back to FIG. 2, to use the diagnostic instrument 10 of the present invention, a user may connect the leads 20, 22 to the power source 12. As discussed above, the leads 20, 22 may have resistors R1, R2 connected in series and joined into a single lead 14. This lead may connect to one end of the LED 16 while the second leg of the LED 16 may connect to a probe (via a resistor R3). The probe 18 may be used to detect a wide range of voltages and may detect both positive and negative polarities at the same time.

It should be understood, of course, that the foregoing relates to exemplary embodiments of the invention and that modifications may be made without departing from the spirit and scope of the invention as set forth in the following claims.

What is claimed is:

1. A diagnostic instrument comprising:
first and second leads adapted to connect to a direct current power source;
first ends of first and second resistors in series in the first and second leads, respectively;
second ends of first and second resistors joined together and connected to a first lead of a detector; and
a probe attached to a second lead of the detector.

2. The diagnostic instrument of claim 1, wherein the detector is a light emitting diode (LED) or a center point meter device.

3. The diagnostic instrument of claim 2, wherein the detector is a tri-LED.

4. The diagnostic instrument of claim 2, wherein the detector includes a first LED and a second LED, a cathode of the first LED connected to an anode of the second LED and an anode of the first LED connected to a cathode of the second LED.

5. The diagnostic instrument of claim 1, further comprising a resistor between the probe and the second lead of the detector.

6. The diagnostic instrument of claim 1, further comprising clips on the first and second leads, the clips adapted to connect to the power source.

7. The diagnostic instrument of claim 1, wherein the power source is a DC battery.

8. The diagnostic instrument of claim 1, wherein the first lead is adapted to connect to one of a positive terminal and a negative terminal of the power source and the second lead is adapted to connect to an other one of the positive terminal and the negative terminal of the power source.

9. A diagnostic instrument comprising:
a direct current power source;
first and second leads connected to the power source;
first ends of first and second resistors in series in the first and second leads, respectively;
second ends of first and second resistors joined together and connected to a first lead of a light emitting diode (LED); and
a probe attached, via a third resistor, to a second lead of the LED.

10. The diagnostic instrument of claim 9, wherein the LED includes a first LED illuminating when the probe detects voltage of a first polarity and a second LED illuminating when the probe detects voltage of a second, opposite polarity.
